(19) United States
(12) Patent Application Publication
(10) Pub. No.: US 2026/0112877 A1
(43) Pub. Date: Apr. 23, 2026

(54) Power Supplies with Overcurrent Protection and Single-Point Fault Protection

(71) Applicant: Weltrend Semiconductor Inc., Hsinchu (TW)

(72) Inventors: Chuan-Shing CHEN, Hsinchu (TW); Chih-Sheng YANG, Hsinchu (TW)

(21) Appl. No.: 19/278,926

(22) Filed: Jul. 24, 2025

(30) Foreign Application Priority Data
Oct. 23, 2024 (TW) 113140343

(51) Int. Cl. H02H 3/02; G01R 19/00; G01R 19/165; H02H 3/32; H02J 4/00

(52) U.S. Cl. CPC H02H 3/025; G01R 19/0092; G01R 19/16504; H02H 3/32; H02J 4/00

(57) ABSTRACT

A power supply supplies power to a load connected between high-voltage and low-voltage power terminals. A high-side current-sensing unit connected to the high-voltage power terminal senses a first output current that the power supply pours to the load, generating a high-side sensing signal. A low-side current-sensing unit connected to the low-voltage power terminal senses a second output current that the power supply drains from the load, generating a low-side sensing signal. One of the high-side current-sensing unit and the low-side current-sensing unit includes a power switch. A power control circuit converts the high-side sensing signal and the low-side sensing signal into high-side sensing value and low-side sensing value respectively, compares the high-side sensing value with the low-side sensing value, and turns OFF the power switch if a difference between the high-side sensing value and the low-side sensing value reaches a predetermined abnormal threshold.

### CROSS-REFERENCE TO RELATED APPLICATION

This application claims priority to and the benefit of Taiwan Application Series Number 113140343 filed on Oct. 23, 2024, which is incorporated by reference in its entirety.

### BACKGROUND

The present disclosure relates generally to power supplies, and more particularly, to power supplies that provide overcurrent protection and single-point fault protection.

Electronic information products have become indispensable tools in people's daily lives. To supply the necessary power for the proper operation of these products, numerous power supplies have been developed. In addition to providing output with the required voltage, current, or power, power supplies must also comply with various safety regulations to prevent potential risks.

One such regulation is IEC-62368, a safety standard for consumer products. IEC-62368 includes specifications for Limited Power Sources (LPS). Furthermore, IEC-62368 imposes specific power limitation requirements on power supplies in the event of a single fault in the circuit, to prevent the risk of fire or electric shock to individuals in contact with the equipment.

Power supplies often include current sensing resistors, which allow the power control circuit to detect the amount of current flowing through a particular path and perform corresponding control actions. However, if the current sensing resistor fails—such as through a short circuit—the power control circuit may misinterpret the actual current, potentially resulting in non-compliance with the Limited Power Source requirements.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified. These drawings are not necessarily drawn to scale. Likewise, the relative sizes of elements illustrated by the drawings may differ from the relative sizes depicted.

The invention can be more fully understood by the subsequent detailed description and examples with references made to the accompanying drawings, wherein:

FIGS. 1 and 2 illustrate power supplies according to embodiments of the present invention;

FIG. 3 illustrates an example of the power control circuit in FIG. 2;

FIG. 4 illustrates a high-side current sensing unit; and

FIGS. 5 and 6 illustrates power supplies according to embodiments of the present invention.

### DETAILED DESCRIPTION

In the following description, numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment”, “an embodiment”, “one example” or “an example” means that a particular feature, structure, or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures, or characteristics may be combined in any suitable combinations and/or subcombinations in one or more embodiments or examples. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

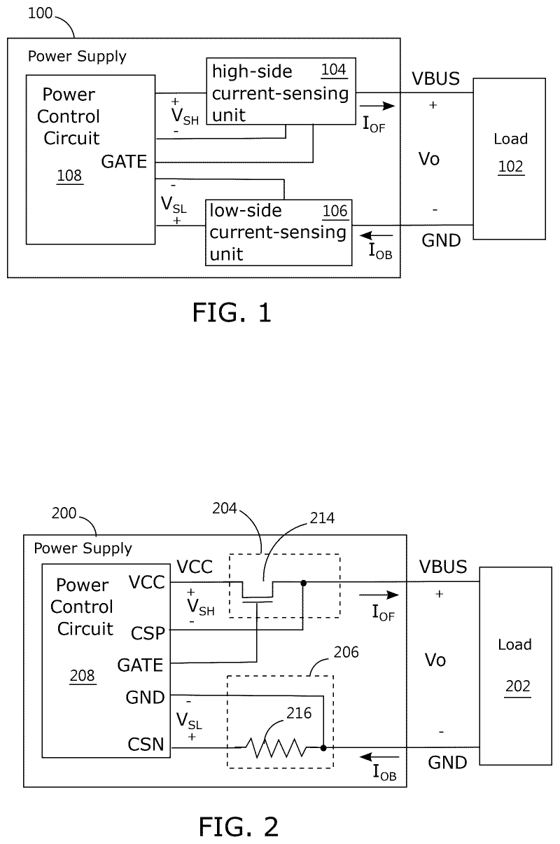

FIG. 1 illustrates power supply 100 according to embodiments of the present invention, which provides output voltage V_{O} to power load 102 through high-voltage power terminal VBUS and low-voltage power terminal GND. Power supply 100 includes power control circuit 108, high-side current-sensing unit 104, and low-side current-sensing unit 106. Power supply 100 pours to load 102 output current I_{OF} via high-voltage power terminal VBUS and drains from load 102 output current I_{OB} via low-voltage power terminal GND. According to circuit theory, under normal conditions, output currents I_{OF} and I_{OB} should be equal in magnitude.

Connected to high-voltage power terminal VBUS, high-side current-sensing unit 104 senses output current I_{OF}, thereby generating high-side sensing signal V_{SH}. Similarly, low-side current sensing unit 106 is connected to low-voltage power terminal GND to sense output current I_{OB}, generating low-side sensing signal V_{SL}.

In FIG. 1, high-side current sensing unit 104 includes a power switch (which will be illustrated later) connected to gate terminal GATE of power control circuit 108.

Power control circuit 108 converts high-side sensing signal V_{SH} and low-side sensing signal V_{SL} into high-side sensing value S_{P} and low-side sensing value S_{N}, respectively. When either high-side sensing value S_{P} or low-side sensing value S_{N} exceeds an overcurrent protection threshold, power control circuit 108 controls the power switch in high-side current-sensing unit 104 to limit output current I_{OF} or I_{OB}.

If either high-side current-sensing unit 104 or low-side current-sensing unit 106 experiences a single-point fault, a short circuit for example, power control circuit 108 can still rely on the remaining functional sensing unit to provide appropriate protection for the power supply 100. For instance, when either high-side sensing value S_{P} or low-side sensing value S_{N} exceeds the overcurrent protection threshold, power control circuit 108 turns off the power switch in high-side current-sensing unit 104, thereby reducing output current I_{OF} or I_{OB} to approximately 0 A.

FIG. 2 illustrates power supply 200 according to embodiments of the invention. Features similar or identical to those in FIG. 1 can be referenced from FIG. 1 and will not be repeated here. In FIG. 2, high-side current-sensing unit 204 includes power switch 214 connected between high-voltage output power line VCC and high-voltage power terminal VBUS, to provide output current I_{OF} to load 202. Low-side current-sensing unit 206 includes sensing resistor 216 connected between low-voltage power terminal GND and low-voltage output power line CSN, used to detect output current I_{OB} flowing from load 202 into low-voltage output power line CSN. For example, high-voltage output power line VCC and low-voltage output power line CSN may be the two output lines of a flyback power supply, respectively, and a voltage source between the two output lines is regulated by the flyback power converter.

When power switch 214 is turned ON, the voltage source between high-voltage output power line VCC and low-voltage output power line CSN supplies power to load 202, generating output currents I_{OF} and I_{OB}. When power switch 214 is turned ON, conducting, the voltage difference between high-voltage output power line VCC and high-voltage power terminal VBUS (i.e., the drain-to-source voltage V_{DS} of power switch 214) can serve as high-side sensing signal V_{SH} provided to power control circuit 208. The voltage across sensing resistor 216 can serve as low-side sensing signal V_{SL}, which is also provided to power control circuit 208.

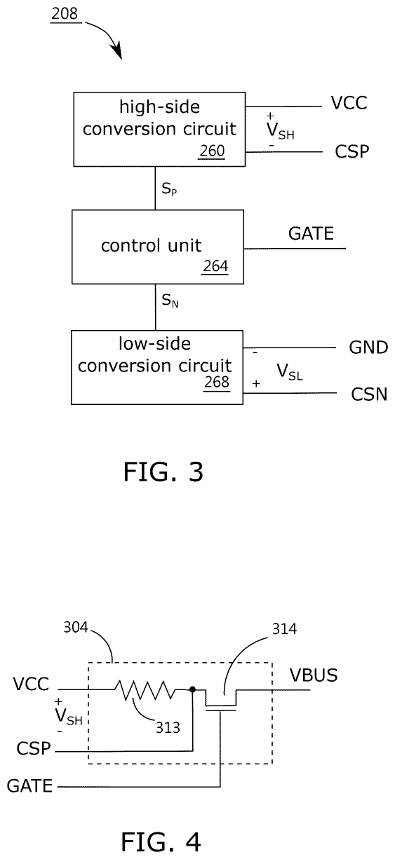

FIG. 3 illustrates an example of power control circuit 208 in FIG. 2, and includes high-side conversion circuit 260, low-side conversion circuit 268, and control unit 264. In this embodiment, the voltage at low-voltage power terminal GND is deemed as 0V for reference. High-side conversion circuit 260 converts high-side sensing signal V_{SH} into high-side sensing value S_{P} and provides it to control unit 264. For example, high-side sensing value S_{P} is a voltage signal referenced to 0V at low-voltage power terminal GND. Low-side conversion circuit 268 converts low-side sensing signal V_{SL} into low-side sensing value S_{N} and provides it to control unit 264. For example, low-side conversion circuit 268 amplifies low-side sensing signal V_{SL}, which has a negative voltage in comparison with 0V at low-voltage power terminal GND, and converts it into a positive-voltage low-side sensing value S_{N} in reference to the 0V (ground voltage) at low-voltage power terminal GND. In this embodiment, the ratio of high-side sensing value S_{P} to output current I_{OF} is approximately equal to the ratio of low-side sensing value S_{N} to output current I_{OB}. In other words, high-side sensing value S_{P} can represent the output current I_{OF}, and low-side sensing value S_{N} output current I_{OB}.

Control unit 264 controls power switch 214 in FIG. 2 via gate terminal GATE based on high-side sensing value S_{P} and low-side sensing value S_{N} to provide appropriate protection. For example, control unit 264 can provide overcurrent protection. Control unit 264 may compare each of high-side sensing value S_{P} and low-side sensing value S_{N} with a predetermined overcurrent protection threshold. If any of high-side sensing value S_{P} and low-side sensing value S_{N} exceeds the predetermined overcurrent protection threshold, control unit 264 turns OFF power switch 214, resulting in output current I_{OF} of 0 A.

In one embodiment, control unit 264 provides single-point fault protection. Control unit 264 compares high-side sensing value S_{P} with low-side sensing value S_{N}. If the difference between high-side sensing value S_{P} and low-side sensing value S_{N} reaches a predetermined abnormal threshold—suggesting that output current I_{OF} is unreasonably different from output current I_{OB}—it indicates a possible failure (such as a short circuit or open circuit) in either high-side current sensing unit 204 or low-side current sensing unit 206. In such a case, control unit 264 can turn OFF power switch 214 to stop supplying power to load 202. At least one of output currents I_{OF} and I_{OB} is cut off when the difference between two values S_{P} and S_{N} reaches the predetermined abnormal threshold.

FIG. 4 illustrates high-side current sensing unit 304, which in one embodiment replaces high-side current sensing unit 204 in FIG. 2. In addition to power switch 314, high-side current-sensing unit 304 further includes sensing resistor 313 connected between power switch 314 and high-voltage output power line VCC. The voltage across sensing resistor 313 serves as high-side sensing signal V_{SH} provided to power control circuit 208.

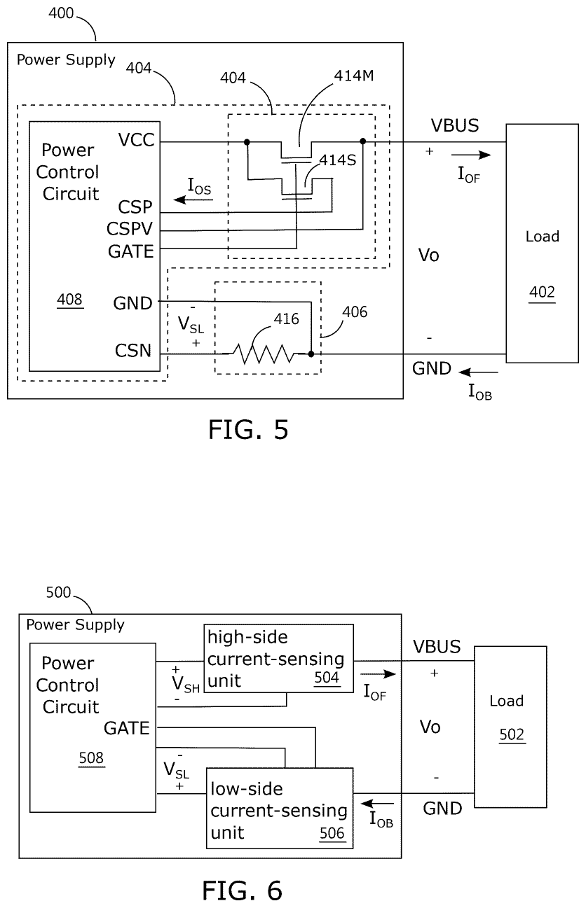

FIG. 5 illustrates power supply 400 according to another embodiment of the present invention. The similarities and identical features with FIGS. 1 and 2 can be inferred from previous descriptions and are not repeated here. In FIG. 5, high-side current-sensing unit 404 includes main power switch 414M and sensing switch 414S. Main power switch 414M, connected between high-voltage output power line VCC and high-voltage power terminal VBUS, is used to supply output current I_{OF} to load 402. Sensing switch 414S is connected between high-voltage output power line VCC and current sensing terminal CSP of power control circuit 408. Power control circuit 408 simultaneously controls both main power switch 414M and sensing switch 414S through gate terminal GATE. When both main power switch 414M and sensing switch 414S are turned ON, power control circuit 408 ensures that both output current I_{OF} flowing through main power switch 414M and sensing current I_{OS} flowing through sensing switch 414S maintain a predetermined proportional relationship. For example, power control circuit 408 may use feedback control to ensure that the voltage at current sensing terminal CSP is approximately equal to the voltage at voltage sensing terminal CSPV (which is also the high-voltage terminal VBUS). Under such conditions, output current I_{OF} and sensing current I_{OS} are approximately in proportion. In this way, power control circuit 408 can also detect sensing current I_{OS} by detecting the voltage at voltage sensing terminal CSPV, which is used as high-side sensing signal V_{SH}. The voltage at voltage sensing terminal CSPV and low-side sensing signal V_{SL} together help power control circuit 408 achieve overcurrent protection and single-point fault protection. In one embodiment, main power switch 414M, sensing switch 414S, and power control circuit 408 are integrated into a single-chip integrated circuit.

Although FIGS. 1, 2, 4, and 5 all show a high-side current-sensing unit with a power switch, the invention is not limited to. FIG. 6 illustrates power supply 500 according to another embodiment of the present invention and has similarities and identical features with FIG. 1 that could be referenced from earlier descriptions and would not be redundantly explained here. In FIG. 6, high-side current-sensing unit 504 does not include a power switch, but low-side current-sensing unit 506 does include a power switch (not shown), which is controlled by power control circuit 508. Similar to the examples shown in FIGS. 2, 4, and 5, low-side current-sensing unit 506 in FIG. 6 may consist of only a power switch, a combination of a power switch in series with a sensing resistor, or a combination of a main power switch and a sensing switch. Power supply 500 is also capable of providing overcurrent protection and single-point fault protection.

While the invention has been described by way of examples and in terms of preferred embodiments, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A power supply for supplying power to a load connected between a high-voltage power terminal and a low-voltage power terminal, comprising:
a high-side current-sensing unit, connected to the high-voltage power terminal, for sensing a first output current that the power supply pours to the load to generate a high-side sensing signal;
a low-side current-sensing unit, connected to the low-voltage power terminal, for sensing a second output current that the power supply drains from the load to generate a low-side sensing signal, wherein one of the high-side current-sensing unit and the low-side current-sensing unit includes a power switch; and
a power control circuit, converting the high-side sensing signal and the low-side sensing signal into high-side sensing value and low-side sensing value respectively, comparing the high-side sensing value with the low-side sensing value, and turning OFF the power switch if a difference between the high-side sensing value and the low-side sensing value reaches a predetermined abnormal threshold.

2. The power supply of claim 1, wherein the high-side current-sensing unit comprises:
the power switch connected between a high-voltage power line and the high-voltage power terminal, to provide the first output current to the load;
wherein the high-side sensing signal is a voltage difference between the high-voltage power line and the high-voltage power terminal.

3. The power supply of claim 1, wherein the high-side current-sensing unit comprises:
the power switch connected to the high-voltage power terminal to provide the first output current to the load; and
a sensing resistor connected between a high-voltage power line and the power switch; and
the high-side sensing signal is the voltage drop across the sensing resistor.

4. The power supply of claim 1, wherein the high-side current-sensing unit comprises:
the power switch connected between a high-voltage power line and the high-voltage power terminal, to provide the first output current to the load; and
a sensing switch connected between the high-voltage power line and the power control circuit;
the power control circuit controls both the power switch and the sensing switch to make the first output current through the power switch and a sensing current through the sensing switch in proportion.

5. The power supply of claim 4, wherein the power switch, the sensing switch, and the power control circuit are integrated into a signal-chip integrated circuit.

6. The power supply of claim 4, wherein the sensing switch is connected between the high-voltage power line and a current-sensing terminal, and the power control circuit is configured to keep a first voltage at the high-voltage power terminal equal to a second voltage at the current-sensing terminal.

7. The power supply of claim 1, wherein the power control circuit compares the high-side sensing value with an overcurrent protection threshold, compares the low-side sensing value with the overcurrent protection threshold, and controls the power switch to limit one of the first and second output currents if one of the high-side sensing value and the low-side sensing value exceeds the overcurrent protection threshold.

8. A protection method in use of a power supply, wherein the power supply supplies power to a load connected between a high-voltage power terminal and a low-voltage power terminal, the protection method comprising:
sensing a first output current that the power supply pours to the load to generate a high-side sensing signal;
sensing a second output current that the power supply drains from the load to generate a low-side sensing signal;
converting the high-side sensing signal and the low-side sensing signal into high-side sensing value and low-side sensing value respectively;
comparing the high-side sensing value with the low-side sensing value;
cutting off at least one of the first and second output currents if a difference between the high-side sensing value and the low-side sensing value reaches a predetermined abnormal threshold.

9. The protection method of claim 8, wherein the power supply comprises a power switch connected between the high-voltage power terminal and a high-voltage power line, the power switch supplies the first output current to the load, and the high-side sensing signal is a voltage difference between the high-voltage power line and the high-voltage power terminal.

10. The protection method of claim 8, wherein the power supply comprises:
a power switch connected to the high-voltage power terminal to provide the first output current to the load; and
a sensing resistor connected between a high-voltage power line and the power switch.

11. The protection method of claim 8, wherein the power supply comprises:
a power switch connected between a high-voltage power line and the high-voltage power terminal, to provide the first output current to the load; and
a sensing switch connected between the high-voltage power line and the power control circuit, to provide a sensing current to the power control circuit; and
the protection method further comprises:
controlling both the power switch and the sensing switch to make the first output current and the sensing current in proportion.

12. The protection method of claim 8, comprising:
comparing the high-side sensing value with an overcurrent protection threshold;
comparing the low-side sensing value with the overcurrent protection threshold; and
controlling the power switch to limit one of the first and second output currents if one of the high-side sensing value and the low-side sensing value exceeds the overcurrent protection threshold.

13. A power supply for supplying power to a load connected between a high-voltage power terminal and a low-voltage power terminal, comprising:
a high-side current-sensing unit, connected to the high-voltage power terminal, for sensing a first output current that the power supply pours to the load to generate a high-side sensing signal;
a low-side current-sensing unit, connected to the low-voltage power terminal, for sensing a second output current that the power supply drains from the load to generate a low-side sensing signal, wherein one of the high-side current-sensing unit and the low-side current-sensing unit includes a power switch; and
a power control circuit, comprising:
a high-side conversion circuit converting the high-side sensing signal into a high-side sensing value;
a low-side conversion circuit converting the low-side sensing signal into a low-side sensing value; and
a control unit comparing the high-side sensing value with the low-side sensing value, and turning OFF the power switch if a difference between the high-side sensing value and the low-side sensing value reaches a predetermined abnormal threshold.

14. The power supply of claim 13, wherein the low-side sensing value is a positive voltage in reference to a ground voltage at the low-voltage power terminal.

15. The power supply of claim 13, wherein the high-side current-sensing unit comprises:
the power switch connected between a high-voltage power line and the high-voltage power terminal, to provide the first output current to the load.

16. The power supply of claim 15, wherein the high-side current-sensing unit further comprises:
a sensing resistor connected between the high-voltage power line and the power switch.

17. The power supply of claim 15, wherein the high-side current-sensing unit further comprises:
a sensing switch connected between the high-voltage power line and the power control circuit, and
the power control circuit controls both the power switch and the sensing switch to make the first output current through the power switch and a sensing current through the sensing switch in proportion.
